(19) United States
(12) Patent Application Publication
(10) Pub. No.: US 2026/0314241 A1
(43) Pub. Date: Oct. 8, 2026

(54) DISPLAY PANEL, PREPARING METHOD THEREOF, AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Yongho Choi, Beijing (CN); Liyan Xuan, Beijing (CN); Ce Zhao, Beijing (CN); Ming Wang, Beijing (CN); Anjun Wang, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 18/996,694

(22) PCT Filed: May 21, 2024
(86) PCT No.: PCT/CN2024/094324

§ 371 Date: Jan. 17, 2025

(30) Foreign Application Priority Data
Jun. 19, 2023 (CN) 202310738592.6

(51) Int. Cl. H10K 59/80; H10D 86/01; H10D 86/40; H10D 86/60; H10K 59/12; H10K 59/121; H10K 59/124; H10K 59/126; H10K 59/131; H10K 59/35; H10K 59/38

(52) U.S. Cl. CPC H10K 59/876; H10D 86/0212; H10D 86/0221; H10D 86/411; H10K 59/1201; H10K 59/1213; H10K 59/124; H10K 59/126; H10K 59/351; H10D 86/423; H10D 86/60; H10K 59/131; H10K 59/38

(57) ABSTRACT

A display panel and a method for preparing the same, and a display device are provided. The display panel includes a substrate, a plurality of sub-pixel units formed on the substrate, and a plurality of MIMIM dual-resonance structures; each sub-pixel unit includes an oxide TFT; the MIMIM dual-resonance structure includes a first metal layer, a first insulator layer, a light absorbing layer, a second insulator layer, and a second metal layer laminated sequentially in that order in a direction away from the substrate; the light absorbing layer is used to absorb incident blue light; a first spacing area is formed between the blue sub-pixel unit and the sub-pixel unit adjacent thereto; the MIMIM dual-resonance structure is arranged in the first spacing area and is located between the blue sub-pixel unit and the oxide TFT of the sub-pixel unit adjacent thereto.

### CROSS-REFERENCE TO RELATED APPLICATION

This application claims priority to Chinese Patent Application No. 202310738592.6 filed in China on Jun. 19, 2023, the entire contents of which are incorporated herein by reference.

### TECHNICAL FIELD

The present disclosure relates to the field of display technology, and in particular to a display panel and a preparing method thereof, and a display device.

### BACKGROUND

Compared with a conventional Organic Light-Emitting Diode (OLED), a White Organic Light-Emitting Diode (WOLED) has been more widely used because of its longer service life and higher luminous efficiency. In a WOLED display device, a pixel unit is composed of a red sub-pixel (R), a green sub-pixel (G), a blue sub-pixel (B) and a white sub-pixel (W). During use, the white light is displayed through the combined light emission of the above sub-pixels. The high-energy short-wavelength blue light in WOLED will affect the characteristics of an oxide Thin Film Transistor (TFT). When the blue light is added to the oxide TFT, the carrier density of the channel increases, and the threshold voltage (Vth) negative shift occurs, which causes reliability problems such as progressive bright spots and unintended brightening of surrounding pixels.

### SUMMARY

An object of the present disclosure is to provide a display panel and a method for preparing the same, and a display device, so as to solve the reliability problems such as progressive bright spots and unintended brightening of surrounding pixels caused by the addition of blue light to oxide TFTs. The specific technical solutions are as follows.

In a first aspect, embodiments of the present application provides a display panel, the display panel includes a substrate, a plurality of sub-pixel units formed on the substrate, and a plurality of Metal-Insulator-Thin Film Metal-Insulator-Metal (MIMIM) dual-resonance structures; the plurality of sub-pixel units include a red sub-pixel unit, a green sub-pixel unit, and a blue sub-pixel unit, each of which includes an oxide TFT; the MIMIM dual-resonance structure includes a first metal layer, a first insulator layer, a light absorbing layer, a second insulator layer, and a second metal layer, which are laminated sequentially in that order in a direction away from the substrate; the first metal layer, the first insulator layer, and the light absorbing layer constitute a lower Fabry-Perot (FP) cavity; the light absorbing layer, the second insulator layer and the second metal layer constitute an upper FP cavity; a spacing area is formed between adjacent sub-pixel units; the second metal layer includes a metal signal line arranged in the spacing area; the orthographic projection of the light absorbing layer onto the substrate and the orthographic projection of the metal signal line onto the substrate have an overlapping area; the light absorbing layer is used to absorb incident blue light; a first spacing area is formed between the blue sub-pixel unit and the sub-pixel unit adjacent thereto; the MIMIM dual-resonance structure is arranged in the first spacing area and is located between the blue sub-pixel unit and the oxide TFT of the sub-pixel unit adjacent thereto.

In some embodiments of the present application, the plurality of sub-pixel units further include: a white sub-pixel unit;
a second spacing area is formed between the white sub-pixel unit and a sub-pixel unit adjacent thereto; the MIMIM dual-resonance structure is arranged in the second spacing area and is located between the white sub-pixel unit and the oxide TFT of the sub-pixel unit adjacent thereto.

In some embodiments of the present application, the oxide TFT includes: an active layer, a gate insulator layer, a gate electrode, an interlayer dielectric layer and a source-drain metal layer laminated sequentially in that order in a direction away from the substrate;
the interlayer dielectric layer covers the gate electrode; and a via hole is provided in the interlayer dielectric layer;
the source-drain metal layer includes a source electrode and a drain electrode, and each of the source electrode and the drain electrode is connected to the active layer through the via hole in the interlayer dielectric layer.

In some embodiments of the present application, the metal signal line and the source-drain metal layer are arranged in the same layer;
the light absorbing layer is arranged in the same layer as the active layer, and the interlayer dielectric layer covers the light absorbing layer.

In some embodiments of the present application, the first metal layer is arranged between the active layer and the substrate, and the first metal layer is a light shielding layer;
the first insulator layer is arranged between the active layer and the first metal layer, and the first insulator layer is a buffer layer;
the interlayer dielectric layer is formed as the second insulator layer;
the light shielding layer, the buffer layer, the light absorbing layer, the interlayer dielectric layer and the metal signal line are arranged in contact with each other sequentially in that order to form a MIMIM dual-resonance structure.

In some embodiments of the present application, the material of the active layer is partially conductive Indium Gallium Zinc Oxide (IGZO); the material of the light absorbing layer is fully conductive IGZO.

In some embodiments of the present application, the display panel further includes a passivation layer, a color filter layer, a planarization layer, and a first electrode which are arranged sequentially in that order in a direction away from the substrate;
the passivation layer is arranged at a side of the source-drain metal layer distal to the substrate, and covers the source-drain metal layer and the metal signal line;
the color filter layer includes a plurality of sub-color filters, each of which is arranged corresponding to a respective one of the sub-pixel units;
the planarization layer covers the color filter layer;
a via hole is provided in the planarization layer and the passivation layer, and the first electrode is connected to the source-drain metal layer through the via hole in the planarization layer and the passivation layer.

In some embodiments of the present application, the display panel further includes: a gate line, the gate line and the metal signal line are arranged to cross each other;

The gate line is connected to the gate of the oxide TFT.

In a second aspect, embodiments of the present application provides a method for preparing a display panel, which is used to prepare the display panel in the above embodiments, and includes:
providing the substrate;
preparing the first metal layer on the substrate;
preparing the first insulator layer on the first metal layer;
preparing the light absorbing layer, the second insulator layer and the oxide TFT on the first insulator layer; the second insulator layer covers the light absorbing layer;
preparing the second metal layer on the second insulator layer;
wherein the first metal layer, the first insulator layer, the light absorbing layer, the second insulator layer and the second metal layer form the MIMIM dual-resonance structure.

In some embodiments of the present application, the oxide TFT includes the active layer, the gate insulator layer, the gate electrode, the interlayer dielectric layer and the source-drain metal layer;
the preparing the light absorbing layer, the second insulator layer and the oxide TFT on the first insulator layer includes:
preparing the IGZO layer on the first insulator layer;
preparing the light absorbing layer and the active layer of the oxide TFT through patterning and conducting processes; wherein the active layer is made of partially-conductive IGZO, and the light absorbing layer is made of conductive IGZO;
preparing the gate insulator layer on the active layer;
preparing the gate electrode on the gate insulator layer; the gate electrode is not in contact with the active layer;
preparing the interlayer dielectric layer on the gate electrode, wherein the interlayer dielectric layer covers the gate electrode and the gate insulator layer to form the second insulator layer;
forming the via hole in the interlayer dielectric layer;
preparing the source-drain metal layer on the interlayer dielectric layer, wherein the source-drain metal layer is connected to the active layer through the via hole in the interlayer dielectric layer.

In some embodiments of the present application, after preparing the second metal layer on the second insulator layer, the method further includes:
preparing a metal signal line in a same layer as the source-drain metal layer, wherein the metal signal lines are formed as a second metal layer;
preparing a passivation layer on the second metal layer;
preparing a color film layer on the passivation layer;
preparing a planarization layer on the color film layer, wherein the planarization layer covers the color film layer;
forming an alignment hole in the planarization layer and the passivation layer;
preparing first electrode on the planarization layer, wherein the first electrode is connected to the source-drain metal layer through the alignment hole in the planarization layer and the passivation layer.

In a third aspect, embodiments of the present application provides a display device, including the display panel in any embodiment of the first aspect.

The beneficial effects of the embodiments of the present disclosure are as follows:
the display panel of the present application includes a MIMIM dual-resonance structure, which is formed with an upper Fabry-Perot (FP) cavity and a lower FP cavity arranged up and down. Light can be reflected in the upper FP cavity or the lower FP cavity. There is a light absorbing layer between the upper FP cavity and the lower FP cavity, and the light absorbing layer is used to absorb incident blue light. Therefore, the MIMIM dual-resonance structure in the display panel of the present application can absorb the incident blue light and can convert a short wavelength into a long wavelength through wavelength shift. The MIMIM dual-resonance structure is arranged in the first spacing area between the blue sub-pixel unit and the sub-pixel unit adjacent thereto, and is located between the blue sub-pixel unit and the oxide TFT of the sub-pixel unit adjacent thereto. In this way, in the process that the blue light is emitted toward the oxide TFT of the sub-pixel unit adjacent to the blue sub-pixel unit, it needs to pass through the MIMIM dual-resonance structure. No matter whether the blue light passes to the upper FP cavity or the lower FP cavity, it will be absorbed, and the blue light cannot propagate to the oxide TFT of the sub-pixel unit adjacent to the blue sub-pixel unit, thereby solving the reliability problems such as progressive bright spots and unintended brightening of surrounding pixels caused by the blue light being added to the oxide TFT.

The method for preparing the display panel of the present application is used to prepare the display panel in the above-mentioned embodiments. Since the display panel of the present application includes the MIMIM dual-resonance structure, the blue light can be absorbed during the process the blue light is emitted toward the oxide TFT of the sub-pixel unit adjacent to the blue sub-pixel unit, so that the blue light cannot be transmitted to the oxide TFT of the sub-pixel unit adjacent to the blue sub-pixel unit. Therefore, the display panel prepared by the method for preparing the display panel of the present application solves the reliability problems such as progressive bright spots and unintended brightening of surrounding pixels caused by the addition of blue light to the oxide TFT.

The display device of the present application includes the display panel according to any one of the embodiments of the first aspect mentioned above. Since the display panel of the present application includes the MIMIM dual-resonance structure, the blue light can be absorbed when the blue light is emitted toward the oxide TFT of the sub-pixel unit adjacent to the blue sub-pixel unit, so that the blue light cannot be transmitted to the oxide TFT of the sub-pixel unit adjacent to the blue sub-pixel unit. Therefore, the display device of the present application can solve the reliability problems such as progressive bright spots and unintended brightening of surrounding pixels caused by the addition of blue light to the oxide TFT.

### BRIEF DESCRIPTION OF THE DRAWINGS

In order to more clearly illustrate the embodiments of the present disclosure or the technical solutions in the prior art, the drawings required for use in the embodiments of the present disclosure or the description of the prior art will be briefly introduced below. Obviously, the drawings in the following description are only some embodiments of the present disclosure, and for ordinary skilled in the art, other embodiments can also be obtained based on these drawings.

FIG. 1 is a diagram illustrating changes in characteristics of an oxide TFT when a light source is introduced to the oxide TFT;

FIG. 2 is a diagram for residual image testing of a display panel in the related art;

FIG. 3 is a layout diagram of a display panel according to embodiments of the present application;

FIG. 4 is a schematic diagram of a MIMIM dual-resonance structure in a display panel according to embodiments of the present application;

FIG. 5 is a schematic diagram of the MIM structure;

FIG. 6a is a diagram showing the relationship between layers of a conventional MIMIM dual-resonance structure;

FIG. 6b is a partial enlarged schematic diagram of the dotted box in FIG. 4;

FIG. 7 is a diagram showing the light absorption capacity of non-conductorized IGZO and conductorized IGZO;

FIG. 8 is a waveform diagram of white light, blue light, red light and green light;

FIG. 9 is a flow chart of a method for preparing a display panel according to embodiments of the present application.

### DESCRIPTION OF REFERENCE NUMERALS

display panel 10; thick metal layer 21; insulator layer 22; thin metal layer 23; substrate 100; MIMIM dual-resonance structure 200; upper FP cavity 201; lower FP cavity 202; first metal layer 210; first insulator layer 220; light absorbing layer 230; second insulator layer 240; second metal layer 250; metal signal line 251; sub-pixel unit 300; red sub-pixel unit 301; green sub-pixel unit 302; blue sub-pixel unit 303; white sub-pixel unit 304; pixel area 300a; TFT area 300b; oxide TFT 310; active layer 311; gate insulator layer 312; gate electrode 313; interlayer dielectric layer 314; source-drain metal layer 315; passivation layer 400; color filter layer 500; sub-color filter 510; planarization layer 600; first electrode 700; gate line 801; first spacing area 901; second spacing area 902.

### DETAILED DESCRIPTION

The following will be combined with the drawings in the embodiments of the present disclosure to clearly and completely describe the technical solutions in the embodiments of the present disclosure. Obviously, the described embodiments are only part of the embodiments of the present disclosure, rather than all the embodiments. Based on the embodiments in the present disclosure, all other embodiments obtained by ordinary skilled in the art based on this application belong to the protection scope of the present disclosure.

The WOLED display panel use oxide Thin-Film Transistors (TFTs). The oxide TFTs have material properties that when a high-energy short-wavelength light source (blue light) is added, the carrier density in the oxide channel increases, causing characteristic changes such as negative shift of threshold voltage (Vth(−)).

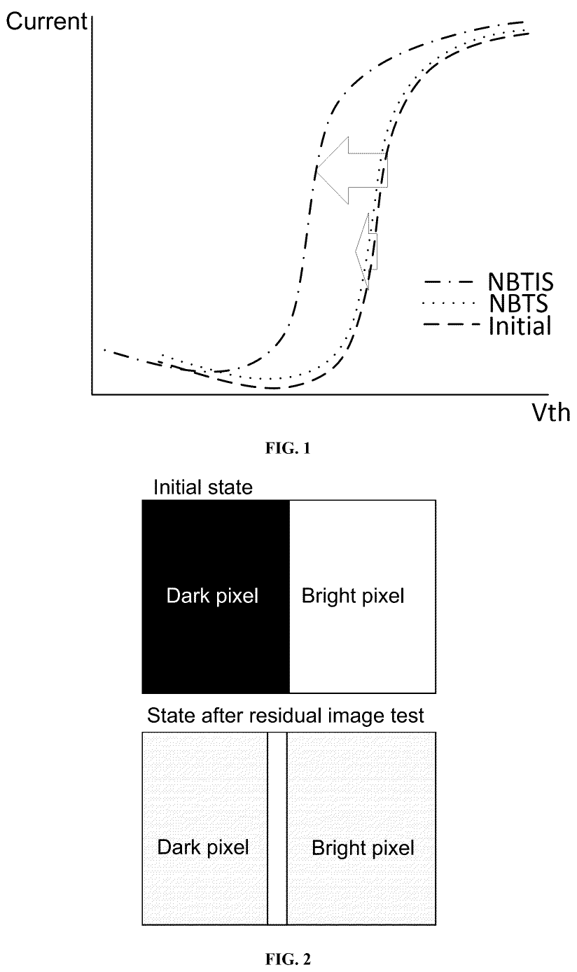

Specifically, as shown in FIG. 1, which is a characteristic change diagram of an oxide TFT when a light source is added to the oxide TFT. The three curves in FIG. 1 are initial, Negative Bias Temperature Stress (NBTS), and NBTIS (Negative Bias Temperature Illumination Stress) characteristic curves. It can be seen that the NBTIS characteristic curve has the largest change, and the threshold voltage has a large negative shift. In this way, a residual image problem will occur during the display process. This characteristic change is caused by the addition of a light source to the oxide TFT. This characteristic fluctuation has a poor reliability problem, that is, due to the poor driving of the progressive bright spot and the adjacent Gate On Array (GOA) TFT, poor linearity occurs, resulting in poor reliability of poor progressiveness.

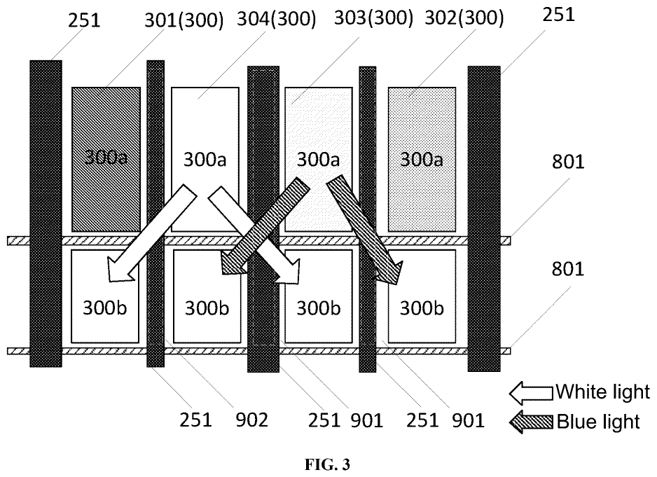

Specifically, as shown in FIG. 2, which illustrates the residual image test of the display panel in the related art. The two color patterns on the left represent dark pixels, the two color patterns on the right represent bright pixels, the two color patterns on the top represent the display image in the initial state, and the two color patterns on the bottom represent the display image after the residual image test. The oxide TFT of the upper left black pattern receives negative bias, and the upper right white pattern receives positive bias stress; at this time, the light generated from the white pattern is transmitted to the oxide TFT of the black pattern adjacent to the white pattern, generating the Vth(−) shift, and due to the change in the characteristics of the oxide TFT, the brightness of the black pattern increases, resulting in brightness at the boundary between the black pattern and white pattern, thereby generating a defect.

In order to solve the reliability problem such as progressive bright spots and unintended brightening of surrounding pixels caused by the addition of the blue light to the oxide TFTs, the present application provides a display panel and a preparation method thereof, and a display device.

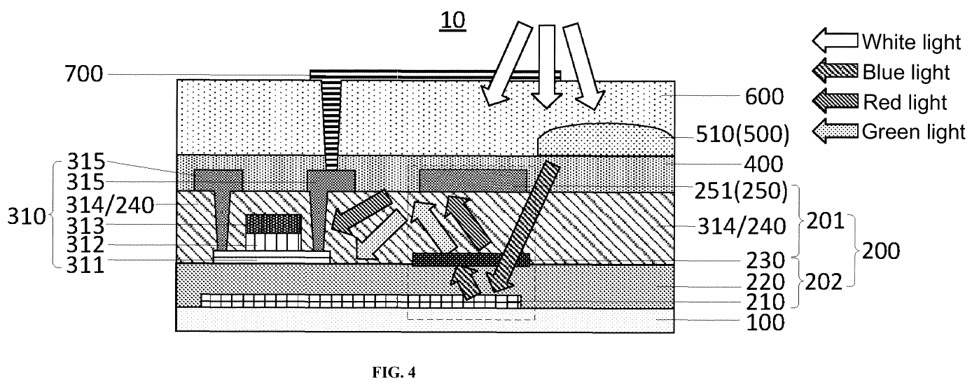

As shown in FIGS. 3 and 4, wherein FIG. 3 is a layout diagram of the display panel 10 according to the embodiments the present application, and FIG. 4 is a schematic diagram of the MIMIM dual-resonance structure 200 in the display panel 10 of the embodiments of the present application. The embodiments of the first aspect of the present application provides a display panel 10, the display panel 10 includes a substrate 100, a plurality of sub-pixel units 300 formed on the substrate 100, and a plurality of MIMIM dual-resonance structures 200; the plurality of sub-pixel units 300 include a red sub-pixel unit 301, a green sub-pixel unit 302, and a blue sub-pixel unit 303, and each sub-pixel unit 300 includes an oxide TFT 310; the MIMIM dual-resonance structure 200 includes a first metal layer 210, a first insulator layer 220, a light absorbing layer 230, a second insulator layer 240, and a second metal layer 250, which are laminated sequentially in that order in a direction away from the substrate 100; the first metal layer 210, the first insulator layer 220 and the light absorbing layer 230 constitute the lower FP cavity 202; the light absorbing layer 230, the second insulator layer 240 and the second metal layer 250 constitute the upper FP cavity 201; a spacing area is formed between adjacent sub-pixel units 300; the second metal layer 250 includes a metal signal line 251 arranged in the spacing area; the orthographic projection of the light absorbing layer 230 onto the substrate 100 and the projection of the metal signal line 251 onto the substrate 100 have an overlapping area; the light absorbing layer 230 is used to absorb incident blue light; a first spacing area 901 is formed between the blue sub-pixel unit 303 and the sub-pixel unit 300 adjacent thereto; the MIMIM dual-resonance structure 200 is arranged in the first spacing area 901 and is located between the blue sub-pixel unit 303 and the oxide TFT 310 of the sub-pixel unit 300 adjacent thereto.

As shown in FIG. 3, the oxide TFT 310 is arranged in the corresponding TFT area 300b, and light is emitted from the pixel area 300a.

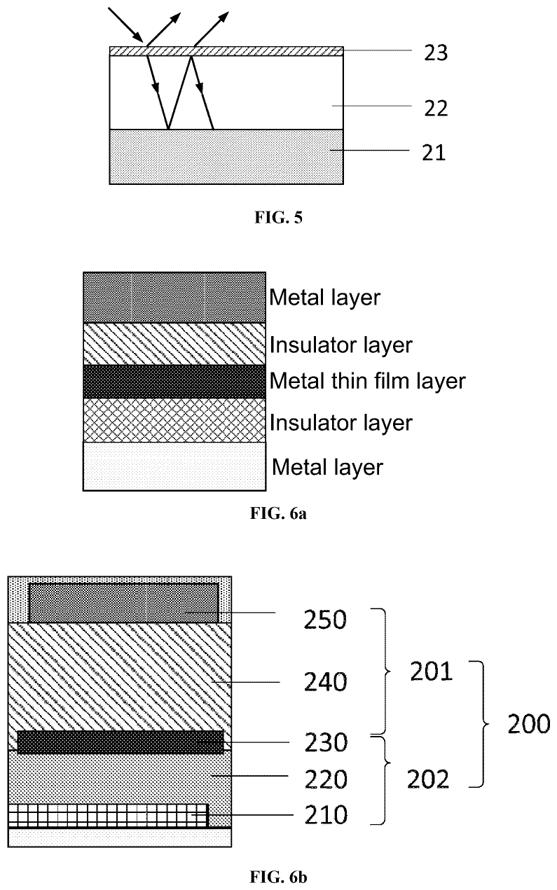

In this application, it introduces a Metal-Insulator-Metal (MIM) structure that can resonate with a Fabry-Perot cavity (FP cavity) as shown in FIG. 5. FIG. 5 is a schematic diagram of the MIM structure, wherein the layer structure from top to bottom includes a thin metal layer 23, an insulator layer 22 and a thick metal layer 21, wherein the thick metal layer 21 is used as a back reflector to reflect light. This resonant structure can selectively remove the light wavelength or perform phase shift by adjusting the thickness of the insulator in the MIM structure. Based on the above, the display panel 10 of the present application is provided with a Metal-Insulator-Thin Film Metal-Insulator-Metal (MIMIM) dual-resonance structure as shown in FIG. 6a. FIG. 6a is a diagram showing the relationship between the layers of a conventional MIMIM dual-resonance structure, which includes a metal layer, an insulator layer, a metal film layer, an insulator layer, and a metal layer from top to bottom, wherein the upper three film layers form an upper cavity, and the lower three film layers form a lower cavity, and the metal film layer serves as a common film layer for the two cavities. As shown in FIG. 6b, FIG. 6b is a partial enlarged schematic diagram of the dotted box in FIG. 4, wherein the second metal layer 250, the second insulator layer 240, the light absorbing layer 230, the first insulator layer 220, and the first metal layer 210 are laminated sequentially from top to bottom, and the film layers shown in FIG. 6b correspond one by one to the film layers shown in FIG. 6a from top to bottom.

The display panel 10 of the present application includes a MIMIM dual-resonance structure 200, and the MIMIM dual-resonance structure 200 is formed with an upper FP cavity 201 and a lower FP cavity 202 arranged up and down. Light can be reflected in the upper FP cavity 201 or the lower FP cavity 202. There is a light absorbing layer 230 between the upper FP cavity 201 and the lower FP cavity 202. The light absorbing layer 230 is used to absorb incident blue light. Therefore, the MIMIM dual-resonance structure 200 in the display panel 10 of the present application can absorb the incident blue light and can convert the short wavelength into a long wavelength through wavelength shift. The MIMIM dual-resonance structure 200 is arranged in the first spacing area 901 between the blue sub-pixel unit 303 and the sub-pixel unit 300 adjacent thereto, and is located between the blue sub-pixel unit 303 and the oxide TFT 310 of the sub-pixel unit 300 adjacent thereto. Thus, in the process that the blue light is emitted to the oxide TFT 310 of the sub-pixel unit 300 adjacent to the blue sub-pixel unit 303, the blue light needs to pass through the MIMIM dual-resonance structure 200. No matter whether the blue light passes to the upper FP cavity 201 or the lower FP cavity 202, the blue light will be absorbed, and the blue light cannot propagate to the oxide TFT 310 of the sub-pixel adjacent to the blue sub-pixel unit 303, thereby solving the reliability problems such as the progressive bright spots and the unintended brightening of the surrounding pixels caused by the blue light being added to the oxide TFT 310.

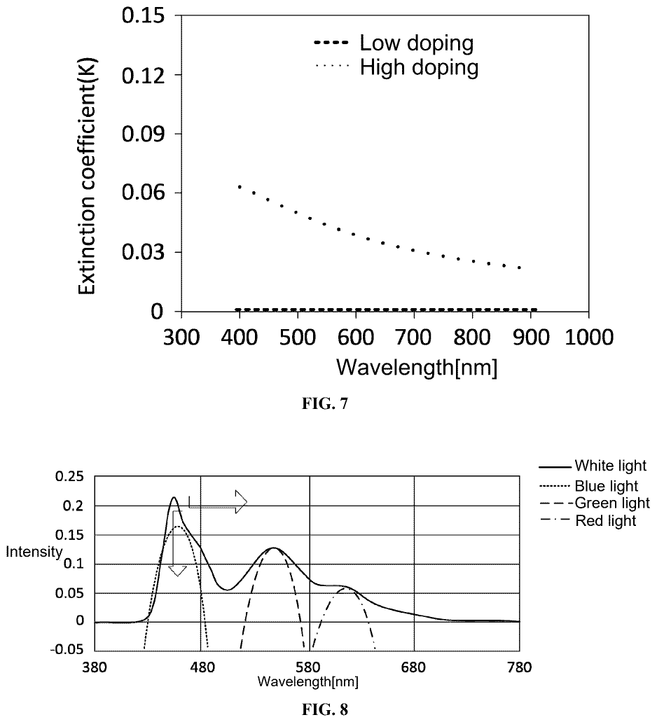

In some embodiments of the present application, the material of the light absorbing layer 230 can be fully conductive Indium Gallium Zinc Oxide (IGZO). The fully conductive IGZO has metallic properties, so it can be used as a metal film layer to form a MIMIM dual-resonance structure 200 together with other film layers. As shown in FIG. 7, which is a light absorption capacity diagram of non-conductive IGZO and conductive IGZO. The low doping curve in FIG. 7 is the curve of non-conductive IGZO, and the high doping curve in FIG. 7 is the curve of conductive IGZO, wherein the horizontal axis represents the wavelength and the vertical axis represents the extinction coefficient. As shown in FIG. 7, the conductive IGZO can eliminate and absorb the short wavelength of 400-600 nm (the wavelength of short-wave blue light is 400 nm-480 nm). When using the MIMIM dual-resonance structure 200 of the resonance structure, the internal reflected light applied from the adjacent sub-pixel unit 300 can be blocked. In addition, the conductive IGZO layer may be used, such that the light source in the short wavelength area of 400-600 nm can be additionally blocked, thereby minimizing the influence of the internally reflected light source on the oxide TFT 310.

In some embodiments of the present application, as shown in FIGS. 2 and 3, the sub-pixel units 300 also include a white sub-pixel unit 304; a second spacing area 902 is formed between the white sub-pixel unit 304 and the sub-pixel unit 300 adjacent thereto; the MIMIM dual-resonance structure 200 is arranged in the second spacing area 902 and is located between the white sub-pixel unit 304 and the oxide TFT 310 of the sub-pixel unit 300 adjacent thereto.

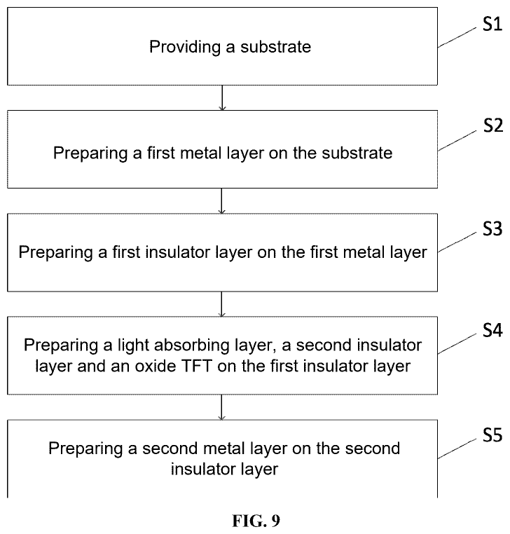

As shown in FIG. 8, which is a waveform diagram of white light, blue light, red light and green light. In FIG. 8, it shows the waveform of white light. The white light has three light sources of blue light, green light and red light. A MIMIM dual-resonance structure 200 is arranged between the white sub-pixel unit 304 and the oxide TFT 310 of the adjacent sub-pixel unit 300 in the second spacing area 902. Accordingly, it can reduce short-wavelength light associated with blue light and form a long wavelength through phase shift.

Specifically, the light absorbing layer 230 can be arranged within the range of the dotted box as shown in FIG. 3, and the orthographic projection of the light absorbing layer 230 onto the substrate 100 falls within the range of the orthographic projection of the metal signal line 251 onto the substrate 100, so that the MIMIM dual-resonance structure 200 is formed within the range of the dotted box. It can be understood that the orthographic projection of the light absorbing layer 230 onto the substrate 100 can also exceed the range of the orthographic projection of the metal signal line 251 onto the substrate 100, as long as the orthographic projections of the first metal layer 210, the first insulator layer 220, the light absorbing layer 230, the second insulator layer 240 and the second metal layer 250 onto the substrate 100 have an overlapping area, and the overlapping area is located between the blue sub-pixel unit 303 or the white sub-pixel unit 304 and the oxide TFT 310 of the sub-pixel unit 300 adjacent thereto, such that the MIMIM dual-resonance structure 200 capable of absorbing the blue light can be formed.

If the MIMIM dual-resonance structures 200 are arranged to cover the dotted box as shown in FIG. 3, that is, arranged in the area of the left and right metal signal lines 251 of the blue sub-pixel unit 303 and the white sub-pixel unit 304, the influence of the light source on the adjacent sub-pixel unit 300 can be minimized, thereby stabilizing the characteristics of the oxide TFT 310 and improving the reliability.

In some embodiments of the present application, as shown in FIG. 4, the oxide TFT 310 includes an active layer 311, a gate insulator layer 312, a gate electrode 313, an interlayer dielectric layer 314 and a source-drain metal layer 315 which are laminated sequentially in a direction away from the substrate 100; the interlayer dielectric layer 314 covers the gate electrode 313; a via hole is provided in the interlayer dielectric layer 314; the source-drain metal layer 315 includes a source electrode and a drain electrode, and each of the source electrode and the drain electrode is connected to the active layer 311 through the via hole in the interlayer dielectric layer 314.

In some embodiments of the present application, as shown in FIG. 4, the metal signal line 251 and the source-drain metal layer 315 are arranged in the same layer; the light absorbing layer 230 and the active layer 311 are arranged in the same layer, and the interlayer dielectric layer 314 covers the light absorbing layer 230. In this way, when the metal signal line 251 and the source-drain metal layer 315 are made of the same material, these two film layers can be formed by one preparation, which is conducive to improving production efficiency. The light absorbing layer 230 and the active layer 311 are similar.

In some embodiments of the present application, as shown in FIG. 4, the first metal layer 210 is arranged between the active layer 311 and the substrate 100, and the first metal layer 210 is a light shielding layer; the first insulator layer 220 is arranged between the active layer 311 and the first metal layer 210, and the first insulator layer 220 is a buffer layer (buffer insulator layer); the interlayer dielectric layer 314 (ILD insulator layer) is formed as the second insulator layer 240; the light shielding layer, the buffer layer, the light absorbing layer 230, the interlayer dielectric layer 314 and the metal signal line 251 are sequentially contacted and arranged to form the MIMIM dual-resonance structure 200. The light absorbing layer 230 is added, such that the MIMIM dual-resonance structure 200 is formed together with other film layers, and there is no need to prepare additional film layers to form the MIMIM dual-resonance structure 200, which is conducive to improving production efficiency.

In some embodiments of the present application, the material of the active layer 311 may be partially conductive IGZO. Specifically, the portion of the active layer 311 that is in direct contact with the source electrode and the drain electrode of the oxide TFT 310 may be conductive.

When the material of the active layer 311 is partially conductive IGZO, the material of the light absorbing layer 230 is fully conductive IGZO, and the active layer 311 and the light absorbing layer 230 are arranged in the same layer, the light absorbing layer 230 can be formed using a general oxide TFT 310 process without requiring additional processes, which is conducive to improving production efficiency.

In some embodiments of the present application, as shown in FIG. 4, the display panel 10 also includes a passivation layer 400, a color filter layer 500, a planarization layer 600 (resin layer) and a first electrode 700, which are arranged sequentially in that order in a direction away from the substrate 100; the passivation layer 400 is arranged on the side of the source-drain metal layer 315 distal to the substrate 100, and covers the source-drain metal layer 315 and the metal signal line 251; the color filter layer 500 includes a plurality of sub-color filters 510, each sub-color filter 510 is arranged corresponding to a sub-pixel unit 300; the planarization layer 600 covers the color filter layer 500; the planarization layer 600 and the passivation layer 400 are provided with an alignment hole, and the first electrode 700 is connected to the source-drain metal layer 315 through the alignment hole in the planarization layer 600 and the passivation layer 400.

Specifically, the color filter layer 500 may include a blue sub-color filter, a green sub-color filter and a red sub-color filter, and the white light presents lights of different colors after passing through the sub-color filters 510 of different colors. The first electrode 700 may be a cathode or an anode, and the first electrode 700 may be connected to the source electrode or drain electrode of the source-drain metal layer 315. The sub-color filter 510 is arranged in the pixel area 300a.

In some embodiments of the present application, as shown in FIG. 3, the display panel 10 further includes a gate line 801, and the gate line 801 and the metal signal line 251 are arranged to intersect each other; the gate line 801 is connected to the gate electrode 313 of the oxide TFT 310.

As shown in FIG. 3, the lines extending in the up-down direction are the metal signal lines 251, which may be respectively a Vdd line (voltage line), a Vdate line (data signal line), Vref line (reference signal line), a Vdate line and a Vdd line from left to right; the two lines extending in the left-right direction are the gate lines 801.

As shown in FIG. 9, which is a flow chart of a method for preparing the display panel 10 according to the embodiments of the present application. An embodiment of the second aspect of the present application provides a method for preparing the display panel 10, which is used to prepare the display panel 10 in the above embodiments, and includes:
step S1, providing a substrate 100;
step S2, preparing a first metal layer 210 on the substrate 100;
step S3, preparing a first insulator layer 220 on the first metal layer 210;
step S4, preparing a light absorbing layer 230, a second insulator layer 240 and an oxide TFT 310 on the first insulator layer 220, wherein the second insulator layer 240 covers the light absorbing layer 230;
step S5, preparing a second metal layer 250 on the second insulator layer 240;
wherein the first metal layer 210, the first insulator layer 220, the light absorbing layer 230, the second insulator layer 240 and the second metal layer 250 form the MIMIM dual-resonance structure 200.

The method for preparing the display panel 10 of the present application is used to prepare the display panel 10 in the above-mentioned embodiments. Since the display panel 10 of the present application includes the MIMIM dual-resonance structure 200, the blue light can be absorbed when the blue light is emitted toward the oxide TFT 310 of the sub-pixel unit 300 adjacent to the blue sub-pixel unit 303, so that the blue light cannot be transmitted to the oxide TFT 310 of the sub-pixel unit 300 adjacent to the blue sub-pixel unit 303. Therefore, the display panel 10 prepared by the above method of the present application solves the reliability problems such as progressive bright spots and unintended brightening of surrounding pixels caused by the addition of blue light to the oxide TFT 310.

In some embodiments of the present application, referring to FIG. 4, the oxide TFT 310 includes an active layer 311, a gate insulator layer 312, a gate electrode 313, an interlayer dielectric layer 314, and a source-drain metal layer 315; the preparing the light absorbing layer 230, the second insulator layer 240, and the oxide TFT 310 on the first insulator layer 220, including:
forming an IGZO layer on the first insulator layer 220;
forming the light absorbing layer 230 and the active layer 311 of the oxide TFT 310 by patterning and conducting processes; wherein the material of the active layer 311 is partially conductive IGZO, and the material of the light absorbing layer 230 is fully conductive IGZO;
forming a gate insulator layer 312 on the active layer 311;
forming a gate electrode 313 on the gate insulator layer 312, wherein the gate electrode 313 is not in contact with the active layer 311;
forming an interlayer dielectric layer 314 on the gate electrode 313, wherein the interlayer dielectric layer 314 covers the gate electrode 313 and the gate insulator layer 312 to form a second insulator layer 240;
forming a via hole in the interlayer dielectric layer 314;
forming a source-drain metal layer 315 on the interlayer dielectric layer 314, wherein the source-drain metal layer 315 is connected to the active layer 311 through the via hole in the interlayer dielectric layer 314.

When the material of the active layer 311 is partially conductive IGZO, the material of the light absorbing layer 230 is fully conductive IGZO, and the active layer 311 and the light absorbing layer 230 are arranged in the same layer, the light absorbing layer 230 can be formed using a general process of the oxide TFT 310 without requiring additional processes, which is conducive to improving production efficiency.

In some embodiments of the present application, after the second metal layer 250 is formed on the second insulator layer 240, the method further includes:
preparing the metal signal line 251 in a same layer as the source-drain metal layer 315, wherein the metal signal line 251 is formed as the second metal layer 250;
preparing a passivation layer 400 on the second metal layer 250;
forming a color filter layer 500 on the passivation layer 400;
preparing a planarization layer 600 on the color filter layer 500, wherein the planarization layer 600 covers the color filter layer 500;
forming an alignment hole in the planarization layer 600 and the passivation layer 400;
forming first electrode 700 on the planarization layer 600, wherein the first electrode 700 is connected to the source-drain metal layer 315 through the alignment hole formed in the planarization layer 600 and the passivation layer 400.

Embodiments of the third aspect of the present application provides a display device, including the display panel 10 in any one of the embodiments of the first aspect.

The display device of the present application includes the display panel 10 in any one of the embodiments of the first aspect mentioned above. Since the display panel 10 of the present application includes the MIMIM dual-resonance structure 200, the blue light can be absorbed when the blue light is emitted toward the oxide TFT 310 of the sub-pixel unit 300 adjacent to the blue sub-pixel unit 303, so that the blue light cannot be transmitted to the oxide TFT 310 of the sub-pixel unit 300 adjacent to the blue sub-pixel unit 303, and thus the display device of the present application can solve the reliability problems such as progressive bright spots and unintended brightening of surrounding pixels caused by the blue light being added to the oxide TFT 310.

It should be noted that, in the present application, relational terms such as first and second, etc. are only used to distinguish one entity or operation from another entity or operation, and do not necessarily require or imply any such actual relationship or order between these entities or operations. Moreover, the terms “comprise”, “include” or any other variants thereof are intended to cover non-exclusive inclusion, so that a process, method, article or device including a series of elements includes not only those elements, but also other elements not explicitly listed, or also includes elements inherent to such process, method, article or device. In the absence of further restrictions, the elements defined by the sentence “include a . . . ” do not exclude the existence of other identical elements in the process, method, article or device including the elements.

Each embodiment in the present application is described in a related manner, and the same or similar parts between the embodiments can be referred to each other, and each embodiment focuses on the differences from other embodiments. In particular, for the system embodiment, since it is basically similar to the method embodiment, the description is relatively simple, and the relevant parts can be referred to the partial description of the method embodiment.

The above are only preferred embodiments of the present disclosure and not intended to limit the protection scope of the present disclosure. Any modification, equivalent replacement, improvement, etc. made within the spirit and principle of the present disclosure are to be included in the protection scope of the present disclosure.

1. A display panel, comprising: a substrate, a plurality of sub-pixel units formed on the substrate, and a plurality of Metal-Insulator-Thin Film Metal-Insulator-Metal (MIMIM) dual-resonance structures; wherein
the plurality of sub-pixel units comprises a red sub-pixel unit, a green sub-pixel unit and a blue sub-pixel unit, and each of the sub-pixel units comprises an oxide Thin Film Transistor (TFT);
the MIMIM dual-resonance structure comprises a first metal layer, a first insulator layer, a light absorbing layer, a second insulator layer and a second metal layer, wherein the first metal layer, the first insulator layer, the light absorbing layer, the second insulator layer and the second metal layer are laminated sequentially in that order in a direction away from the substrate; the first metal layer, the first insulator layer and the light absorbing layer constitute a lower Fabry-Perot (FP) cavity; the light absorbing layer, the second insulator layer and the second metal layer constitute an upper FP cavity;
a spacing area is formed between adjacent ones of the sub-pixel units;
the second metal layer comprises a metal signal line arranged in the spacing area; an orthographic projection of the light absorbing layer onto the substrate overlaps an projection of the metal signal line onto the substrate at an overlapping area; the light absorbing layer is configured to absorb incident blue light;
a first spacing area is formed between the blue sub-pixel unit and a sub-pixel unit adjacent to the blue sub-pixel unit; the MIMIM dual-resonance structure is arranged in the first spacing area, and is located between the blue sub-pixel unit and the oxide TFT of the sub-pixel unit adjacent to the blue sub-pixel unit.

2. The display panel according to claim 1, wherein the plurality of sub-pixel units further comprises a white sub-pixel unit;
a second spacing area is formed between the white sub-pixel unit and a sub-pixel unit adjacent to the white sub-pixel unit; the MIMIM dual-resonance structure is arranged in the second spacing area, and is located between the white sub-pixel unit and the oxide TFT of the sub-pixel unit adjacent to the white sub-pixel unit.

3. The display panel according to claim 1, wherein the oxide TFT comprises an active layer, a gate insulator layer, a gate electrode, an interlayer dielectric layer and a source-drain metal layer, wherein the active layer, the gate insulator layer, the gate electrode, the interlayer dielectric layer and the source-drain metal layer are laminated sequentially in that order in the direction away from the substrate;
the interlayer dielectric layer covers the gate electrode, and a via hole is provided in the interlayer dielectric layer;
the source-drain metal layer comprises a source electrode and a drain electrode, and each of the source electrode and the drain electrode is connected to the active layer through the via hole in the interlayer dielectric layer.

4. The display panel according to claim 3, wherein the metal signal line and the source-drain metal layer are arranged in a same layer;
the light absorbing layer and the active layer are arranged in a same layer, and the interlayer dielectric layer covers the light absorbing layer.

5. The display panel according to claim 4, wherein
the first metal layer is arranged between the active layer and the substrate, and the first metal layer is a light shielding layer;
the first insulator layer is arranged between the active layer and the first metal layer, and the first insulator layer is a buffer layer;
the interlayer dielectric layer is formed as the second insulator layer;
the light shielding layer, the buffer layer, the light absorbing layer, the interlayer dielectric layer and the metal signal line are arranged in contact with each other sequentially in that order to form the MIMIM dual-resonance structure.

6. The display panel according to claim 1, wherein a material of the active layer is partially conductive Indium Gallium Zinc Oxide (IGZO); and a material of the light absorbing layer is fully conductive IGZO.

7. The display panel according to claim 5, wherein the display panel further comprises a passivation layer, a color filter layer, a planarization layer and a first electrode, wherein the passivation layer, the color filter layer, the planarization layer and the first electrode are arranged sequentially in that order in the direction away from the substrate;
the passivation layer is arranged at a side of the source-drain metal layer distal to the substrate, and covers the source-drain metal layer and the metal signal line;
the color filter layer comprises a plurality of sub-color filters, and each of the sub-color filters is arranged corresponding to a respective one of the sub-pixel units;
the planarization layer covers the color filter layer;
the planarization layer and the passivation layer are provided with an alignment hole, and the first electrode is connected to the source-drain metal layer through the alignment hole in the planarization layer and the passivation layer.

8. The display panel according to claim 7, wherein the display panel further comprises a gate line, and the gate line and the metal signal line are arranged to intersect each other;
the gate line is connected to the gate electrode of the oxide TFT.

9. A method for preparing a display panel, wherein the method is used to prepare the display panel according to claim 1, and comprises:
providing the substrate;
preparing the first metal layer on the substrate;
preparing the first insulator layer on the first metal layer;
preparing the light absorbing layer, the second insulator layer and the oxide TFT on the first insulator layer, wherein the second insulator layer covers the light absorbing layer;
preparing the second metal layer on the second insulator layer;
wherein the first metal layer, the first insulator layer, the light absorbing layer, the second insulator layer and the second metal layer form the MIMIM dual-resonance structure.

10. The method according to claim 9, wherein the oxide TFT comprises an active layer, a gate insulator layer, a gate electrode, an interlayer dielectric layer and a source-drain metal layer;
the preparing the light absorbing layer, the second insulator layer and the oxide TFT on the first insulator layer comprises:
preparing an IGZO layer on the first insulator layer;
forming the light absorbing layer and the active layer of the oxide TFT through patterning and conducting processes, wherein a material of the active layer is partially conductive IGZO, and a material of the light absorbing layer is conductive IGZO;
preparing the gate insulator layer on the active layer;
preparing the gate electrode on the gate insulator layer, wherein the gate electrode is not in contact with the active layer;
preparing the interlayer dielectric layer on the gate electrode, wherein the interlayer dielectric layer covers the gate electrode and the gate insulator layer to form the second insulator layer;
forming the via hole in the interlayer dielectric layer;
preparing the source-drain metal layer on the interlayer dielectric layer, wherein the source-drain metal layer is connected to the active layer through the via hole in the interlayer dielectric layer.

11. The method according to claim 10, wherein after preparing the second metal layer on the second insulator layer, the method further comprises:
preparing a metal signal line in a same layer as the source-drain metal layer, and forming the metal signal line as the second metal layer;
preparing a passivation layer on the second metal layer;
preparing a color film layer on the passivation layer;
preparing a planarization layer on the color film layer, wherein the planarization layer covers the color film layer;
forming an alignment hole in the planarization layer and the passivation layer;
preparing a first electrode on the planarization layer, wherein the first electrode is connected to the source-drain metal layer through the alignment hole of the planarization layer and the passivation layer.

12. A display device, comprising the display panel according to claim 1.

13. The display panel according to claim 2, wherein the oxide TFT comprises an active layer, a gate insulator layer, a gate electrode, an interlayer dielectric layer and a source-drain metal layer, wherein the active layer, the gate insulator layer, the gate electrode, the interlayer dielectric layer and the source-drain metal layer are laminated sequentially in that order in the direction away from the substrate;
the interlayer dielectric layer covers the gate electrode, and a via hole is provided in the interlayer dielectric layer;
the source-drain metal layer comprises a source electrode and a drain electrode, and each of the source electrode and the drain electrode is connected to the active layer through the via hole in the interlayer dielectric layer.

14. The display device according to claim 12, wherein the plurality of sub-pixel units further comprises a white sub-pixel unit;
a second spacing area is formed between the white sub-pixel unit and a sub-pixel unit adjacent to the white sub-pixel unit; the MIMIM dual-resonance structure is arranged in the second spacing area, and is located between the white sub-pixel unit and the oxide TFT of the sub-pixel unit adjacent to the white sub-pixel unit.

15. The display device according to claim 12, wherein the oxide TFT comprises an active layer, a gate insulator layer, a gate electrode, an interlayer dielectric layer and a source-drain metal layer, wherein the active layer, the gate insulator layer, the gate electrode, the interlayer dielectric layer and the source-drain metal layer are laminated sequentially in that order in the direction away from the substrate;
the interlayer dielectric layer covers the gate electrode, and a via hole is provided in the interlayer dielectric layer;
the source-drain metal layer comprises a source electrode and a drain electrode, and each of the source electrode and the drain electrode is connected to the active layer through the via hole in the interlayer dielectric layer.

16. The display device according to claim 15, wherein the metal signal line and the source-drain metal layer are arranged in a same layer;
the light absorbing layer and the active layer are arranged in a same layer, and the interlayer dielectric layer covers the light absorbing layer.

17. The display device according to claim 16, wherein
the first metal layer is arranged between the active layer and the substrate, and the first metal layer is a light shielding layer;
the first insulator layer is arranged between the active layer and the first metal layer, and the first insulator layer is a buffer layer;
the interlayer dielectric layer is formed as the second insulator layer;
the light shielding layer, the buffer layer, the light absorbing layer, the interlayer dielectric layer and the metal signal line are arranged in contact with each other sequentially in that order to form the MIMIM dual-resonance structure.

18. The display device according to claim 12, wherein a material of the active layer is partially conductive Indium Gallium Zinc Oxide (IGZO); and a material of the light absorbing layer is fully conductive IGZO.

19. The display device according to claim 17, wherein the display panel further comprises a passivation layer, a color filter layer, a planarization layer and a first electrode, wherein the passivation layer, the color filter layer, the planarization layer and the first electrode are arranged sequentially in that order in the direction away from the substrate;
the passivation layer is arranged at a side of the source-drain metal layer distal to the substrate, and covers the source-drain metal layer and the metal signal line;
the color filter layer comprises a plurality of sub-color filters, and each of the sub-color filters is arranged corresponding to a respective one of the sub-pixel units;
the planarization layer covers the color filter layer;
the planarization layer and the passivation layer are provided with an alignment hole, and the first electrode is connected to the source-drain metal layer through the alignment hole in the planarization layer and the passivation layer.

20. The display device according to claim 19, wherein the display panel further comprises a gate line, and the gate line and the metal signal line are arranged to intersect each other;
the gate line is connected to the gate electrode of the oxide TFT.
